(19) United States
(12) Patent Application Publication
(10) Pub. No.: US 2008/0201090 A1
(43) Pub. Date: Aug. 21, 2008

(54) Method of evaluating characteristic of magnetic head

(75) Inventor: Minoru Sawada, Kawasaki (JP)

Correspondence Address: GREER, BURNS & CRAIN, 300 S WACKER DR, 25TH FLOOR, CHICAGO, IL, 60606, US

(73) Assignee: Fujitsu Limited, Kawasaki-shi (JP)

(21) Appl. No.: 12/006,417

(22) Filed: Jan. 2, 2008

(30) Foreign Application Priority Data
Feb. 19, 2007 (JP) 2007-037641

(51) Int. Cl. G01R 33/12

(52) U.S. Cl. 702/57

(57) ABSTRACT

In the method of evaluating a characteristic of a magnetic head, a failure of a measuring equipment can be detected without stopping shipment of magnetic heads which have been previously evaluated, reevaluating the magnetic heads and stopping the measuring operations. The method of evaluating characteristics of the magnetic head comprises the steps of: storing measured data, which are a prescribed characteristic of the magnetic head measured by a measuring equipment, in storing means; detecting if the measuring equipment is failed or not on the basis of the measured data; and evaluating characteristics of the magnetic head when a failure of the measuring equipment is not detected in the detecting step.

### BACKGROUND OF THE INVENTION

The present invention relates to a method of evaluating a characteristic of a magnetic head by measuring a prescribed characteristic of the magnetic head with a measuring equipment.

Conventionally, a prescribed characteristic of a magnetic head, e.g., p-H characteristic of a read-element, has been evaluated, by a measuring equipment, before shipment.

The p-H characteristic is a time-lapse variation characteristic of output values of the read-element, e.g., voltage, current intensity, resistance, which is measured when external magnetic fields are applied to the read-element through which a prescribed sense current passes.

Japanese Patent Kokai Gazette No. 6-150264 discloses a conventional method of measuring the p-H characteristic (a conventional method of examining a magnetoresistance effect head) and an equipment for measuring the p-H characteristic (a conventional inspection equipment). In the disclosed method of measuring the p-H characteristic, a sine-waved alternate external magnetic field is applied to read-elements (MR heads) arranged in a head block (raw bar), which has been cut from a wafer, and electromagnetic conversion characteristics of the read-elements with respect to variation of the external magnetic fields are measured.

FIG. 7 is a block diagram schematically showing a circuit of the p-H measuring equipment (MR head inspecting equipment).

In FIG. 7, Helmholtz coils (air-core coils) 10 apply external magnetic fields to a read-element, and major axes of the Helmholtz coils 10 are vertically arranged in parallel. The Helmholtz coils (air-core coils) 10 are electrically connected to a Helmholtz coil power source 11, which is controlled by a control computer 12. A mounting table 13a is located between the Helmholtz coils 10, and a raw bar 14 is temporally fixed on the mounting table 13a.

The raw bar 14 is produced by the steps of: forming a lot of read-elements on a wafer by a thin film forming process; cutting the wafer along lines of the read-elements to form into bars; and polishing floating surfaces of the bars by a gap depth process. Therefore, the raw bar 14 includes a plurality of the read-elements. Note that, the raw bar 14 will be cut to form into the separated read-elements.

A probe pin 15 is capable of contacting an output electrode of each read-element included in the raw bar 14.

A probe cable, which is connected to the probe pin 15, is connected to a constant-current power source 20 so as to pass an electric current through the read-element electrically connected to the power source 20 via the probe pin 15. Further, an oscilloscope 21, which displays output voltage of the read-element, and the control computer 12, which receives the output voltage so as to perform analysis, are connected to the probe cable.

The Helmholtz coil power source 11 and the constant-current power source 20 are connected to the control computer 12, so the power sources 11 and 20 are controlled by the control computer 12.

The control computer 12 controls the Helmholtz coil power source 11 so as to apply a sine-waved alternate external magnetic field to the read-elements arranged in the raw bar 14 and measures variation of output voltage (electromagnetic conversion characteristic) of each read-element with respect to variation of the external magnetic field by the probe pin 15 and the probe cable.

FIG. 8 shows a conventional process of measuring and evaluating a p-H characteristic.

Firstly, magnetic heads formed in the raw bar 14, which has been cut from the wafer, are set in the above described p-H measuring equipment. Then, a p-H characteristic of each magnetic head included in the raw bar 14 is measured (step S11). The measured data are stored in storing means of the control computer 12 (step S12).

Next, quality of the magnetic head is determined on the basis of a prescribed sorting standard (step S13). If the magnetic head meets the sorting standard, the magnetic head is shipped (step S14). On the other hand, if the magnetic head does not meet the sorting standard, the measured data of the magnetic head are analyzed (step S15).

In the analyzing step (step S15), the abnormal measured data are analyzed if the abnormal data are caused by a failure of the measuring equipment or a failure of the object magnetic head.

Note that, the “failure of the measuring equipment” includes: failures of the measuring equipment itself; failures of peripheral units of the measuring equipment, e.g., probe pin; configuration faults of the measuring equipment; and operation faults of the measuring equipment, e.g., poor contact of the probe pin 15.

Next, the analysis result of the measured data is determined.

In this step, if the abnormal measured data are caused by a failure of the object magnetic head, the raw bar 14 including the object magnetic head and the wafer from which the raw bar 14 are separated are not shipped as bad products (step S17).

On the other hand, if the abnormal measured data are caused by the failure of the measuring equipment, the failure is recovered (step S16), and the process is returned to the step S11 so as to measure the p-H characteristic of the same magnetic head in the raw bar again. Further, the steps following the step S11 are executed again.

The sorting standard of the step S13, which is used to examine the quality of the magnetic head, is different from that used to determine the cause of the abnormal measured data in the step S15.

Therefore, even if the measuring equipment is failed, the magnetic head is sometimes determined as a good product in the step S13. In case that the failure of the measuring equipment is found in the step S15, there is a possibility that magnetic heads which have been measured before executing the step S15 are determined as good products, in the step 11, in spite of abnormal data measured by the failed measuring equipment.

In case that the failure of the measuring equipment is detected in the step S15, the existence of the failure must be checked for the magnetic heads which have been determined as good ones in the step S13 on the basis of the sorting standard of the step S15. Namely, in the conventional method of evaluating a characteristic of a magnetic head, if the failure of the measuring equipment is found from the measured data, qualities of the magnetic heads whose characteristics have been once evaluated must be evaluated again.

In case that the measured data of the magnetic heads, whose characteristics have been evaluated, have a tendency to indicate the failure of the measuring equipment, the failure of the measuring equipment must be recovered, the magnetic heads must be reevaluated.

As described above, in the conventional method of evaluating a characteristic of a magnetic head, when the failure of the measuring equipment is found, shipment of the magnetic heads which have been determined as shippable products must be stopped, the magnetic heads whose characteristics have been once evaluated must be evaluated again, the previously-executed steps must be executed again, so workload must be increased.

Since the failure of the measuring equipment causes the re-execution of the numbers of previously-executed steps and unscheduled operations, the measuring operations must be frequently stopped so as to detect the failure of the measuring equipment. Therefore, time loss must be greater.

### SUMMARY OF THE INVENTION

The present invention was conceived to solve the above described problems.

An object of the present invention is to provide a method of evaluating a characteristic of a magnetic head, in which a failure of a measuring equipment can be detected without stopping shipment of magnetic heads which have been previously evaluated, reevaluating the magnetic heads and stopping the measuring operations.

To achieve the object, the present invention has following constitutions.

Namely, the method of evaluating characteristics of a magnetic head comprises the steps of: storing measured data, which are a prescribed characteristic of the magnetic head measured by a measuring equipment, in storing means; detecting if the measuring equipment is failed or not on the basis of the measured data; and evaluating characteristics of the magnetic head when a failure of the measuring equipment is not detected in the detecting step.

With this method, the characteristic of the magnetic is evaluated when the failure of the measuring equipment is not detected. Even if the failure of the measuring equipment is detected, stopping shipment of magnetic heads which have been previously evaluated and reevaluating the magnetic heads can be avoided. The existence of the failure of the measuring equipment is detected for each of the magnetic heads, so the failure of the measuring equipment can be detected without stopping the measuring operation.

In the method, output values of a read-element of the magnetic head may be measured, as the measured data, by the measuring equipment with applying a magnetic field, which is continuously varied between an upper limit value and a lower limit value, to the magnetic head a plurality of times, the measured data may be stored in the storing means in the storing step, the failure of the measuring equipment may be detected in the detecting step on the basis of variation of output ranges, which are found from the measured data of the plurality of times, and each of the output ranges may be defined as a difference between the output value of the read-element, which is measured when the magnetic field of the upper limit value is applied, and that of the read-element, which is measured when the magnetic field of the lower limit value is applied.

With this method, the variation of the output ranges of the read-element, which is caused by poor contact of an abraded probe pin of the measuring equipment, partial disconnection of a probe cable thereof, etc., can be suitably detected.

In the method, the output values of the read-element of the magnetic head may be measured, as the measured data, by the measuring equipment with applying the magnetic field, which is continuously varied between the upper limit value and the lower limit value, to the magnetic head, the measured data may be stored in the storing means in the storing step, the failure of the measuring equipment may be detected in the detecting step on the basis of variation of interceptions of linear expressions, and each of the linear expressions may be defined as a linear expression indicating a relationship between variation of the magnetic field indicated by the measured data and variation of the output values of the read-element in each value zone, which is defined by dividing a value range between the upper limit value and the lower limit value by a prescribed value.

With this method, the variation of the output ranges of the read-element and the variation of the interceptions with respect to the variation of the magnetic field, which is caused by poor contact of the abraded probe pin of the measuring equipment, partial disconnection of the probe cable thereof, etc., can be suitably detected.

In the method, the output values of the read-element of the magnetic head may be measured, as the measured data, by the measuring equipment with applying the magnetic field, which is continuously varied between the upper limit value and the lower limit value, to the magnetic head a plurality of times, and the measured data may be stored in the storing means in the storing step, and the failure of the measuring equipment may be detected in the detecting step on the basis of variation of the output values of the read-element, which are found from the measured data of the plurality of times.

With this method, the variation of the output ranges of the read-element, which is caused by poor contact of the abraded probe pin of the measuring equipment, partial disconnection of the probe cable thereof, etc., can be suitably detected.

In the method, the failure of the measuring equipment may be detected in the detecting step on the basis of not only the variation but also measurement of Barkhausen jump included in the measured data.

With this method, by detecting the failure of the measuring equipment on the basis of the measurement of Barkhausen jump, discontinued parts of the measured data can be used as an item of detecting the failure of the measuring equipment. Therefore, violent variation of the output of the read-element, which is caused by the poor contact, etc., is used as an item thereof, so that the failure of the measuring equipment can be highly accurately detected.

By employing the method of the present invention, the failure of the measuring equipment can be detected without stopping shipment of magnetic heads which have been previously evaluated, reevaluating the magnetic heads and stopping the measuring operations.

### BRIEF DESCRIPTION OF THE DRAWINGS

Embodiments of the present invention will now be described by way of examples and with reference to the accompanying drawings, in which:

FIG. 1 is a flow chart of the method of evaluating a characteristic of a magnetic head relating to the present invention;

FIG. 2A is a graph showing a magnetic field applied; FIG. 2B is a graph showing an output of a read-element with respect to the magnetic field;

FIGS. 3A and 3B are graphs of measured data, wherein no failure of a measuring equipment is detected;

FIGS. 3C-3J are graphs of measured data, wherein a failure of the measuring equipment is detected;

FIG. 4 is an explanation view showing Barkhausen jump;

FIG. 5 is an explanation view of detecting the failure of the measuring equipment in a detecting step of Example 2;

FIG. 6 is an explanation view of detecting the failure of the measuring equipment in the detecting step of Example 3;

FIG. 7 is a block diagram of the conventional p-H measuring equipment; and

FIG. 8 is a flow chart of the conventional method of evaluating a characteristic of a magnetic head.

### DETAILED DESCRIPTION OF THE EMBODIMENTS

Preferred embodiments of the present invention will now be described in detail with reference to the accompanying drawings.

Note that, a structure of a p-H measuring equipment of the present embodiment is the same as that of the conventional p-H measuring equipment, so the structural elements explained in BACKGROUND OF THE INVENTION are assigned the same symbols and explanation will be omitted.

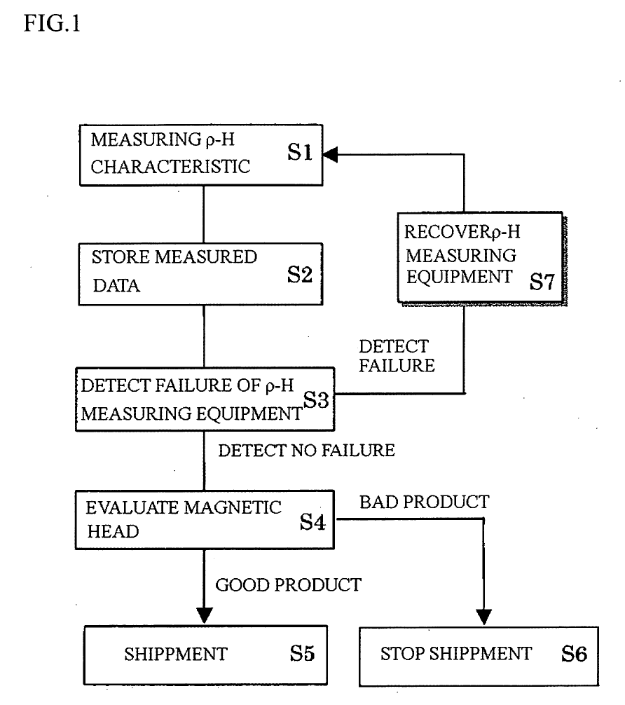

FIG. 1 is a flow chart of the entire method of evaluating a p-H characteristic of the magnetic head relating to the present embodiment.

### (Storing Step)

Firstly, magnetic heads formed in the raw bar 14, which has been cut from a wafer, are set in the p-H measuring equipment. Then, the p-H characteristic of each magnetic head included in the raw bar 14 is measured

### (Step S1).

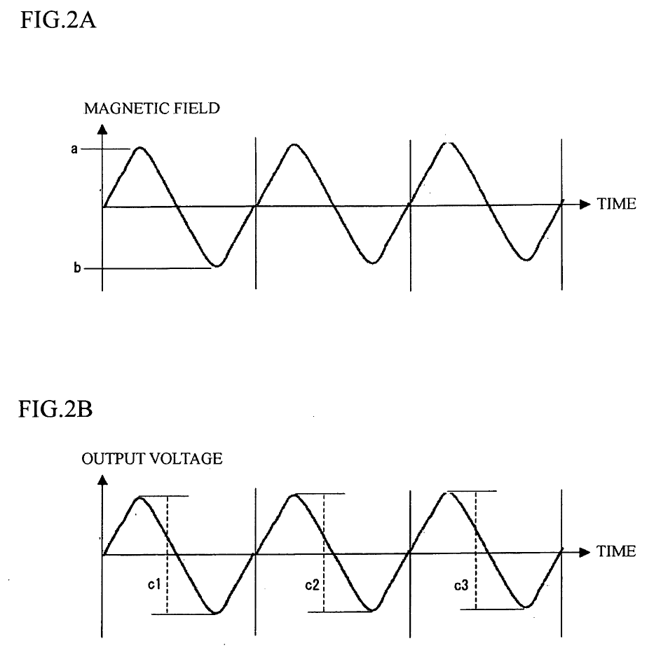

To measure the characteristic, the control computer 12 controls the Helmholtz coil power source 11 so as to measure output values (output voltage) of the read-element of the magnetic head, by the p-H measuring equipment, with applying a magnetic field shown in FIG. 2A, which is continuously varied between an upper limit value a and a lower limit value b, to the magnetic head a plurality of times, e.g., three times (three cycles).

The control computer 12 stores the measured data (the output values of the read-element) in the storing means, e.g., RAM, of the control computer 12 (step S2).

### (Detecting Step)

Next, a control section of the control computer 12 determines if the p-H measuring equipment is failed or not on the basis of the measured data (step S3). Note that, the detailed detecting process will be described later.

In the detecting step (step S3), if a failure of the p-H measuring equipment is detected, the failure of the p-H measuring equipment is recovered (step S7), and then the process is returned to the step S1 so as to measure the p-H characteristic of the same magnetic head in the raw bar 14 again. Further, the steps following the step S2 are executed again.

### (Evaluating Step)

If the failure of the p-H measuring equipment is detected in the detecting step (step S3), the control section of the control computer 12 evaluates the p-H characteristic of the magnetic head on the basis of the measured data (step S4). In this step, quality of the magnetic head is determined by comparing the measured data with the prescribed sorting standard as well as the conventional method. Namely, the magnetic head is sorted as a good one or a bad one on the basis of the sorting standard.

If the magnetic head meets the sorting standard (sorted as a good one), the magnetic head is shipped (step S5). On the other hand, if the magnetic head does not meet the sorting standard (sorted as a bad one), shipment of the raw bar including the bad magnetic head and the wafer from which the raw bar has been separated are stopped (step S6).

In the above described method of evaluating the magnetic head, the characteristic of the magnetic head is evaluated in case that no failure of the p-H measuring equipment is detected. Therefore, the characteristic of the magnetic head is evaluated when the measuring equipment is not failed. Even if the failure of the p-H measuring equipment is detected, stopping shipment of magnetic heads which have been previously evaluated and reevaluating the magnetic heads can be avoided. The existence of the failure of the measuring equipment is detected for each of the magnetic heads, so the failure of the p-H measuring equipment can be detected without stopping the measuring operation.

Preferably, only a failure of the p-H measuring equipment is highly accurately detected, without detecting an abnormal characteristic of the magnetic head, in the determining step (step S3).

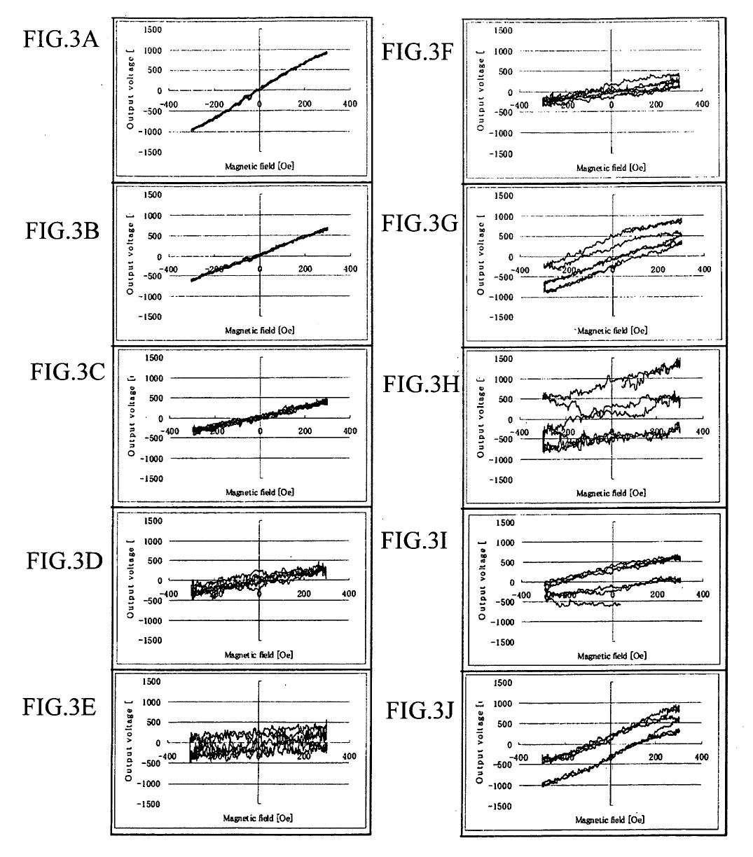

FIGS. 3A and 3B are graphs of the measured data, wherein no failure of the p-H measuring equipment is detected. The measured data are output voltage of the read-element with respect to an external magnetic field applied to the magnetic head three times (three cycles). On the other hand, FIGS. 3C-3J are graphs of the measured data, wherein the p-H measuring equipment is failed by poor contact caused by abrasion of the probe pin 15, partial disconnection of the probe cable, etc.

The inventor of the present invention has studied differences of the measured data between the case in which the p-H measuring equipment was not failed and the case in which the p-H measuring equipment was failed, and differences between abnormal measured data caused by the magnetic head itself and abnormal measured data caused by the failed p-H measuring equipment. As the results of the study, the inventor found a method of detecting the failure of the p-H measuring equipment on the basis of the measured data.

Firstly, in case that the p-H measuring equipment was not failed, the output voltage with respect to the intensity of the magnetic field, which was applied a plurality of times (three cycles), was almost constant as shown in FIGS. 3A and 3B. In many cases that the magnetic head was failed too, the output voltage with respect to the same external magnetic field was almost constant.

On the other hand, in case that the p-H measuring equipment was failed by, e.g., poor contact caused by abrasion of the probe pin 15, partial disconnection of the probe cable, etc., the output voltage with respect to the intensity of the magnetic field, which was applied a plurality of times (three cycles), was varied as shown in FIGS. 3C-3J. Namely, in case that the p-H measuring equipment was failed, the output voltage with respect to the same external magnetic field was varied.

According to the results, the inventor of the present invention found that the poor contact in the p-H measuring equipment, which was caused by abrasion of the probe pin 15, partial disconnection of the probe cable, etc., could be separately detected from failures of the magnetic head on the basis of the variation of the output voltage of the read-element with respect to the same external magnetic field, which was included in the measured data.

Concrete examples of measuring the variation of the output values of the read-element with respect to the same external magnetic field will be explained.

### EXAMPLE 1

FIG. 2B is a graph showing the variation of the output voltage of the read-element with respect to the magnetic field whose variation is shown in FIG. 2A.

In Example 1, the control section of the control computer 12 calculated output ranges c1, c2 and c3 (see FIG. 2B, which were found from the measured data (output voltage of the read-element with respect to the magnetic field applied three times (three cycles) as shown in FIG. 2A). Each of the output ranges c1, c2 and c3 was defined as a difference between the output voltage of the read-element, which was measured when the magnetic field of the upper limit value a was applied, and that of the read-element, which was measured when the magnetic field of the lower limit value b was applied.

The control section of the control computer 12 calculated variation of the output ranges c1, c2 and c3 of the three times (three cycles) and detected the existence of the failure of the measuring equipment on the basis of the variation thereof.

For example, in Example 1, the control section of the control computer 12 calculated absolute values of differences between the output ranges c1, c2 and c3, i.e., |c1-c2|, |c2-c3| and |c3-c1|. In case that the maximum absolute value of the three was greater than a prescribed threshold value, the p-H measuring equipment was determined as the failed p-H measuring equipment.

The threshold value was defined according to types of magnetic heads. For example, in case that the upper limit value a applied to the external magnetic field was about 300 Oe and the lower limit value b applied thereto was about −300 Oe, the p-H measuring equipment was determined as the failed p-H measuring equipment when the maximum absolute value of the three was greater than the threshold value of 53.2 μV.

Preferably, in the detecting step, the failure of the measuring equipment may be detected on the basis of not only the variation but also measurement of Barkhausen jump included in the measured data.

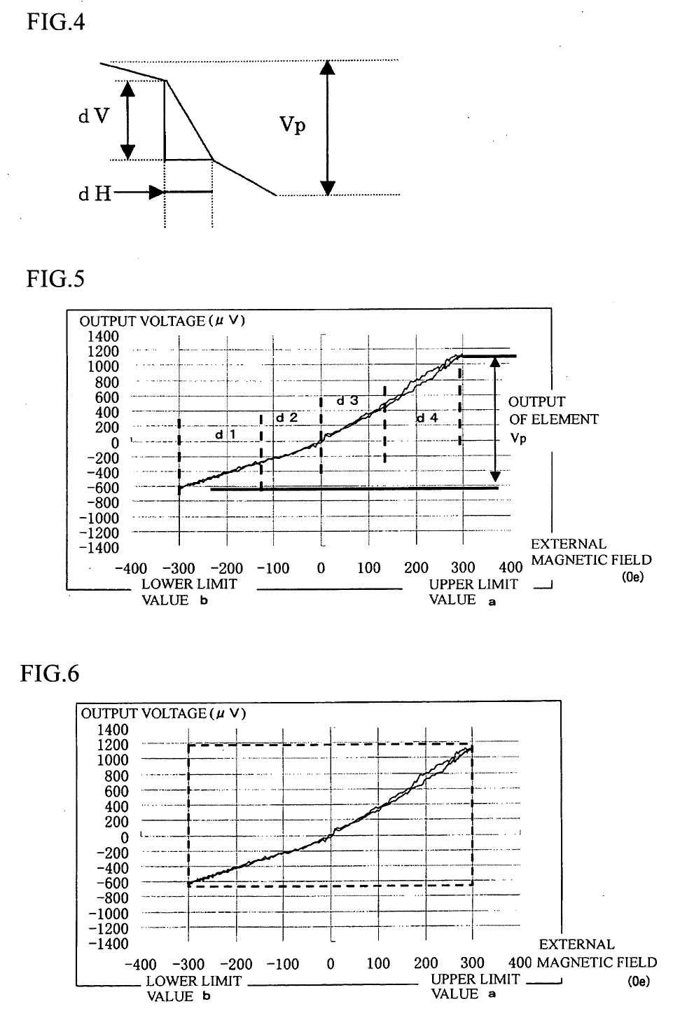

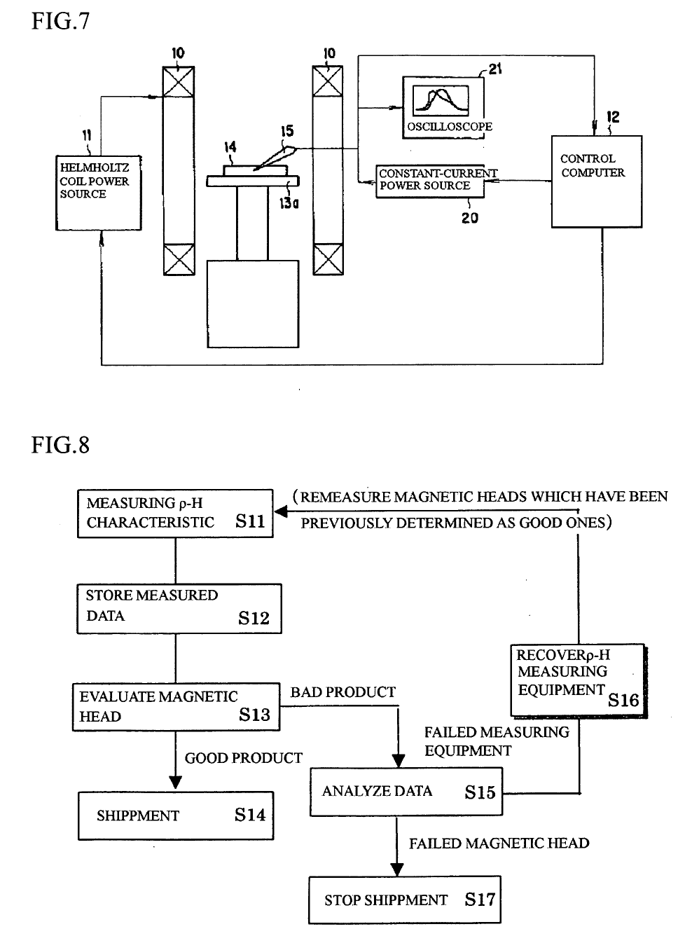

As shown in FIG. 4, the measurement BN of Barkhausen jump is indicated as the following formula:

BN=((dV/dH)/Vp)×100(%)

wherein dV is output voltage of the read-element; dH is variation of a unit magnetic field; and Vp is entire variation of the voltage.

In case that the measured data include said variation and the Barkhausen jump, which is one of items of logical AND operation and greater than a prescribed threshold value, the p-H measuring equipment was determined as the failed measuring equipment.

For example, the threshold value is 10-20%, preferably 14-15%. Note that, the threshold value is not limited to the examples.

By adding the item of the Barkhausen jump, noises included in the output signals of the read-element, which are caused by said poor contact, can be detected, so that the failure of the p-H measuring equipment can be highly accurately detected.

### EXAMPLE 2

FIG. 5 shows a graph of the output voltage of the read-head of the magnetic head included in the measured data. The output voltage was measured, by the p-H measuring equipment, with applying one cycle of the magnetic field, which was continuously varied between the upper limit value a and the lower limit value b, to the magnetic head.

As shown in FIG. 5, the relationship between the external magnetic field and the output voltage of the read-element was indicated as a linear graph. When the applied external magnetic field is x and the output voltage is y, the relationship between the both can be approximately indicated by the following linear expression:

y=px+q

wherein p is a constant inclination and q is a constant interception.

In the detecting step S3, as shown in FIG. 5, the control section of the control computer 12 divided a value range between the upper limit value a and the lower limit value b, by a prescribed value, into value zones d1, d2, d3 and d4 and calculated linear expressions, each of which indicated a relationship between the magnetic field and the output voltage of the read-element in each value zone. For example, the linear expression of each of the value zones d1, d2, d3 and d4 can be set up by calculating the inclination p and the interception q of a linear line, which connects an uppermost coordinate of the measured data in the value zone and a lowermost coordinate thereof in the same value zone.

By applying one cycle of the external magnetic field shown in FIG. 2A, each of the value zones d1, d2, d3 and d4 included the measured data of two times, so eight linear expressions were calculated.

The control section of the control computer 12 detects the failure of the measuring equipment on the basis of variation of the interceptions q1-q8 of the eight linear expressions.

For example, in Example 2, the control section of the control computer 12 calculated absolute values of differences between the interceptions, i.e., |q1-q2|, |q2-q3| . . . |q7-q8| and |q8-q1|. In case that the maximum absolute value of the eight was greater than a prescribed threshold value, the p-H measuring equipment was determined as the failed p-H measuring equipment.

Preferably, in Example 2 too, the failure of the measuring equipment may be detected on the basis of not only the variation but also measurement of Barkhausen jump as one of items of logical AND operation.

### EXAMPLE 3

FIG. 6 shows a graph of the output voltage of the read-head of the magnetic head included in the measured data. The output voltage was measured, by the p-H measuring equipment, with applying one cycle of the magnetic field, which was continuously varied between the upper limit value a and the lower limit value b, to the magnetic head.

In the detecting step S3, the control section of the control computer 12 calculated variation of the output values of the read-element with respect to the external magnetic fields. For example, differences of the output values (voltage) with respect to the external magnetic field applied twice were integrated as shown in FIG. 6 and calculated an area between graphs so as to calculate the variation. In case that the area between the graphs or percentage of the area between the graphs with respect to an entire variation, which was indicated as an area enclosed by dashed lines shown in FIG. 6, was greater than a prescribed threshold value, the p-H measuring equipment was determined as the failed p-H measuring equipment.

Preferably, in Example 3 too, the failure of the measuring equipment may be detected on the basis of not only the variation but also measurement of Barkhausen jump as one of items of logical AND operation.

The invention may be embodied in other specific forms without departing from the spirit of essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A method of evaluating a characteristic of a magnetic head, comprising the steps of:
storing measured data, which are a prescribed characteristic of said magnetic head measured by a measuring equipment, in storing means;
detecting if said measuring equipment is failed or not on the basis of the measured data; and
evaluating characteristics of said magnetic head when a failure of said measuring equipment is not detected in said detecting step.

2. The method according to claim 1,
wherein output values of a read-element of said magnetic head are measured, as the measured data, by said measuring equipment with applying a magnetic field, which is continuously varied between an upper limit value and a lower limit value, to said magnetic head a plurality of times, and said measured data are stored in said storing means in said storing step, and
wherein the failure of said measuring equipment is detected in said detecting step on the basis of variation of output ranges, which are found from said measured data of the plurality of times, and each of the output ranges is defined as a difference between the output value of the read-element, which is measured when the magnetic field of the upper limit value is applied, and that of the read-element, which is measured when the magnetic field of the lower limit value is applied.

3. The method according to claim 2,
wherein the output values of the read-element of said magnetic head are measured, as the measured data, by said measuring equipment with applying the magnetic field, which is continuously varied between the upper limit value and the lower limit value, to said magnetic head, and said measured data are stored in said storing means in said storing step, and wherein the failure of said measuring equipment is detected in said detecting step on the basis of variation of interceptions of linear expressions, and each of the linear expressions is defined as a linear expression indicating a relationship between variation of the magnetic field indicated by the measured data and variation of the output values of the read-element in each value zone, which is defined by dividing a value range between the upper limit value and the lower limit value by a prescribed value.

4. The method according to claim 2,
wherein the output values of the read-element of said magnetic head are measured, as the measured data, by said measuring equipment with applying the magnetic field, which is continuously varied between the upper limit value and the lower limit value, to said magnetic head a plurality of times, and said measured data are stored in said storing means in said storing step, and
wherein the failure of said measuring equipment is detected in said detecting step on the basis of variation of the output values of the read-element, which are found from said measured data of the plurality of times.

5. The method according to claim 2,
wherein the failure of said measuring equipment is determined in said detecting step on the basis of not only said variation but also measurement of Barkhausen jump included in the measured data.

6. The method according to claim 3,
wherein the failure of said measuring equipment is detected in said detecting step on the basis of not only said variation but also measurement of Barkhausen jump included in the measured data.

7. The method according to claim 4,
wherein the failure of said measuring equipment is detected in said detecting step on the basis of not only said variation but also measurement of Barkhausen jump included in the measured data.
